(19) United States
(12) Patent Application Publication
(10) Pub. No.: US 2014/0002881 A1
(43) Pub. Date: Jan. 2, 2014

(54) SELF-POWERED ELECTROCHROMIC DEVICES USING A SILICON SOLAR CELL

(71) Applicant: Electronics and Telecommunications Research Institute, (US)

(72) Inventor: Tae-Youb Kim, Seoul (KR)

(73) Assignee: Electronics and Telecommunications Research Institute, Daejeon (KR)

(21) Appl. No.: 13/737,909

(22) Filed: Jan. 9, 2013

(30) Foreign Application Priority Data
Jun. 28, 2012 (KR) 10-2012-0069987

(51) Int. Cl. G02F 1/155; H01L 31/18

(52) U.S. Cl. CPC G02F 1/155; H01L 31/18; Y10S 977/774; Y10S 977/948
USPC 359/266; 438/69; 977/774; 977/948

(57) ABSTRACT

Provided is an electrochromic device with a solar cell. The device may include first and second substrates spaced apart from and facing each other, an electrolytic layer between the first substrate and the second substrate, a first electrode between the first substrate and the electrolytic layer, a second electrode between the second substrate and the electrolytic layer, an electrochromic layer between the first electrode and the electrolytic layer, and a counter electrode between the second electrode and the electrolytic layer. The counter electrode may be a silicon solar cell.

### CROSS-REFERENCE TO RELATED APPLICATIONS

This U.S. non-provisional patent application claims priority under 35 U.S.C. §119 to Korean Patent Application No. 10-2012-0069987, filed on Jun. 28, 2012, in the Korean Intellectual Property Office, the entire contents of which are hereby incorporated by reference.

### BACKGROUND OF THE INVENTION

Example embodiments of the inventive concept relate to an electrochromic device, and in particular, to an electrochromic device with a solar cell.

In electrochromic devices, electrochromic effect can be produced by electrochemical reaction. For example, the electrochromic device may include an electrochromic layer exhibiting reversibly changeable optical properties, when it is electrochemically oxidized or reduced. So far, the electrochromic devices have been used in vehicles (e.g., car or plane) or building windows for a specific purpose of blocking the sunlight. However, the electrochromic devices have not been applied to reflective display (especially, large outdoor displays), and up to now, an external power should be provided at the outside of the electrochromic device.

### SUMMARY

Embodiments of the inventive concepts provide a self-powered electrochromic device with a silicon solar cell.

According to example embodiments of the inventive concepts, an electrochromic device may include first and second substrates spaced apart from and facing each other, an electrolytic layer between the first substrate and the second substrate, a first electrode between the first substrate and the electrolytic layer, a second electrode between the second substrate and the electrolytic layer, an electrochromic layer between the first electrode and the electrolytic layer, and a counter electrode between the second electrode and the electrolytic layer. The counter electrode may be a silicon solar cell.

In example embodiments, the counter electrode may include silicon quantum dots.

In example embodiments, the counter electrode may include at least one of silicon nitride, silicon carbide, amorphous silicon, or poly silicon.

In example embodiments, the counter electrode may be configured to contain or store hydrogen ions.

In example embodiments, the counter electrode may include a first doped layer doped with at least one of boron (B), aluminum (Al) or gallium (Ga), and a second doped layer doped with at least one of phosphorus (P), arsenic (As) or antimony (Sb).

According to example embodiments of the inventive concepts, a method of fabricating an electrochromic device may include providing a first substrate and a second substrate, providing an electrolytic layer between the first substrate and the second substrate, providing a first electrode between the first substrate and the electrolytic layer, providing a second electrode between the second substrate and the electrolytic layer, providing an electrochromic layer between the first electrode and the electrolytic layer, and providing a counter electrode between the second electrode and the electrolytic layer. The providing of the counter electrode may include forming a silicon layer provided with silicon quantum dots, doping the silicon layer with impurities, and thermally treating the silicon layer doped with the impurities.

In example embodiments, the forming of the silicon layer provided with the silicon quantum dots may include forming a first doped silicon layer, and forming a second doped silicon layer.

In example embodiments, the forming of the first doped silicon layer may be performed using at least one of boron (B), aluminum (Al) or gallium (Ga) as dopants, and the forming of the second doped silicon layer may be performed using at least one of phosphorus (P), arsenic (As) or antimony (Sb) as dopants.

In example embodiments, the forming of the silicon layer provided with the silicon quantum dots may be performed at a temperature of 1100° C. or less using one of plasma enhanced chemical vapor deposition (PECVD), atmospheric pressure CVD, low pressure CVD, or metal organic CVD.

According to example embodiments of the inventive concepts, an electrochromic device may include a first electrode provided on a first substrate, a counter electrode provided on the first electrode to convert solar energy into electric energy, an electrolytic layer provided on the counter electrode, an electrochromic layer provided on the electrolytic layer and electrically connected to the counter electrode, a second electrode provided on the electrochromic layer, and a second substrate provided on the second electrode. The counter electrode may include a silicon layer, in which hydrogen ions may be contained.

In example embodiments, the electrochromic layer may include an anodic coloration material or a cathodic coloration material.

In example embodiments, the anodic coloration material may include at least one of vanadium oxide, chromium oxide, manganese oxide, iron oxide, cobalt oxide, nickel oxide, rhodium oxide, or iridium oxide.

In example embodiments, the cathodic coloration material may include titanium oxide, copper oxide, molybdenum oxide, tungsten oxide, niobium oxide, or tantalum oxide.

In example embodiments, the electrolytic layer may include at least one of tantalum pentoxide (Ta₂O₅), poly 2-acrylamino-2-methylpropane sulfonic acid, or poly (ethylene oxide).

### BRIEF DESCRIPTION OF THE DRAWINGS

Example embodiments will be more clearly understood from the following brief description taken in conjunction with the accompanying drawings. FIGS. 1 through 3 represent non-limiting, example embodiments as described herein.

FIG. 1 is a sectional view illustrating an electrochromic device according to example embodiments of the inventive concept.

FIG. 2 is a flow chart illustrating a method of fabricating a counter electrode according to example embodiments of the inventive concept.

FIG. 3 is a sectional view illustrating an electrochromic device according to other example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

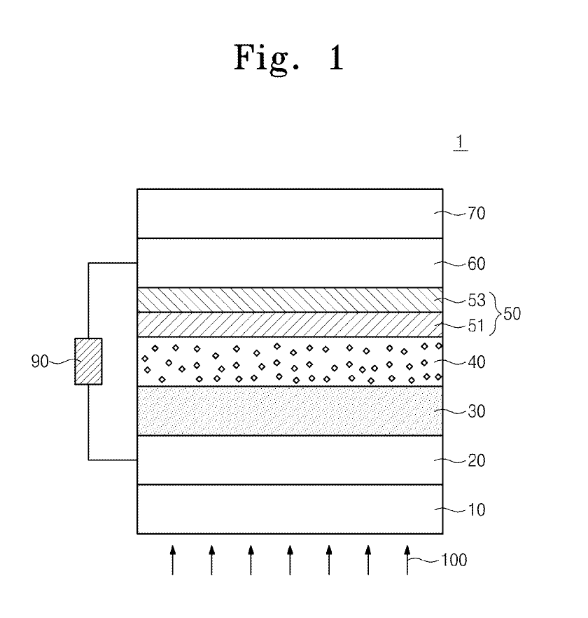

FIG. 1 is a sectional view illustrating an electrochromic device according to example embodiments of the inventive concept.

Referring to FIG. 1, an electrochromic device 1 may include a first substrate 10 and a second substrate 70 spaced apart from and facing each other, an electrolytic layer 40 between the first substrate 10 and the second substrate 70, a first electrode 20 between the first substrate 10 and the electrolytic layer 40, a second electrode 60 between the second substrate 70 and the electrolytic layer 40, an electrochromic layer 30 between the first electrode 20 and the electrolytic layer 40, and a counter electrode 50 between the second electrode 60 and the electrolytic layer 40.

The first substrate 10 may be a transparent substrate. For example, the first substrate 10 may be one of a glass substrate, a plastic substrate, an indium tin oxide (ITO) substrate, or a fluorine-doped tin oxide (FTO) substrate.

The first electrode 20 may be provided on the first substrate 10. The first electrode 20 may include a transparent conductive oxide (TCO) layer. For example, the first electrode 20 may include a layer made of zinc oxide (ZnO), tin oxide (SnO2), indium tin oxide (ITO), aluminium-doped zinc oxide (ZnO:Al), boron-doped zinc oxide (ZnO:B), or aluminum zinc oxide (AZO).

The electrochromic layer 30 may be provided on the first electrode 20. The electrochromic layer 30 may be configured in such a way that its color is changed by an electric current passing therethrough, and this enables to control optical transmittance or reflectance of the electrochromic device 1. In example embodiments, the electrochromic layer 30 may include an inorganic coloration material. The inorganic coloration material may be one of cathodic coloration materials and anodic coloration materials. The cathodic coloration material may be colored by a cathodic reaction and decolored by an anodic reaction. The cathodic coloration materials may include at least one of vanadium oxide, chromium oxide, manganese oxide, iron oxide, cobalt oxide, nickel oxide, rhodium oxide, or iridium oxide. For example, the cathodic coloration materials may include a layer of WO₃, TiO₂, or MO₃. The anodic coloration materials may be colored by an anodic reaction and decolored by a cathodic reaction. The anodic coloration materials may include at least one of titanium oxide, copper oxide, molybdenum oxide, tungsten oxide, niobium oxide, or tantalum oxide. For example, the anodic coloration materials may include a layer of Ni (OH)₂, CoO₂, or IrO₂. In other example embodiments, the electrochromic layer 30 may include at least one of organic coloration materials. The organic coloration materials may include a polyaniline layer.

The electrolytic layer 40 may be provided on the electrochromic layer 30. The electrolytic layer 40 may be configured to supply a redox material, which may be reacted with the electrochromic layer 30. The electrolytic layer 40 may be a solid electrolytic layer. In example embodiments, the electrolytic layer 40 may include a solid inorganic electrolyte (e.g., tantalum pentoxide (Ta₂O₅)). In other example embodiments, the electrolytic layer 40 may include an organic electrolyte, such as poly 2-acrylamino-2-methylpropane sulfonic acid or poly (ethylene oxide). Further, the electrolytic layer 40 may further include compounds serving as electro-donor and electron-acceptor, and this enables to increase a reaction speed of the redox reaction. For example, the electrolytic layer 40 may be formed a ferrocene layer.

The counter electrode 50 may be provided on the electrolytic layer 40.

The counter electrode 50 may be configured to include at least one silicon-containing layer. In example embodiments, the counter electrode 50 may include at least one of an amorphous silicon layer and a poly silicon layer. In other embodiments, the counter electrode 50 may include at least one of a silicon nitride layer or a silicon carbide layer. Further, the counter electrode 50 may be configured to have high content of hydrogen ion. The counter electrode 50 may further include a silicon nano crystal layer. Here, the “silicon nano crystal layer” may be a generic term for nano-sized fine structures (e.g., silicon quantum dots) including nano-sized crystalline silicon particles distributed in a silicon layer. Each of the silicon particles may have a spherical shape, but example embodiments of the inventive concept may not be limited thereto. The presence of the silicon quantum dots may contribute to increase the content of hydrogen ion in the counter electrode 50. In example embodiments, the counter electrode 50 may include a first doped layer 51 and a second doped layer 53. One of the first and second doped layers 51 and 53 may be a p-type doped layer, in which holes are majority carriers, and the other may be an n-type doped layer, in which electrons are majority carriers. In example embodiments, the p-type doped layer may be doped with include boron (B), aluminum (Al), and/or gallium (Ga) as impurities or dopants, while the n-type doped layer may be doped to include phosphorus (P), arsenic (As), and/or antimony (Sb) as impurities. The first doped layer 51 and the second doped layer 53 may be in contact with each other.

The counter electrode 50 may serve as an ion-storing layer. The ion-storing layer may be used to store ions when the electrochromic layer 30 is colored or decolorized. This enables to increase a color-changing speed or efficiency of the electrochromic device 1. In other words, ion-storing ability of the counter electrode 50 can be increased with increasing the content of hydrogen ion in the counter electrode 50. The presence of the silicon quantum dots may contribute to increase the content of hydrogen ion in the counter electrode 50.

In example embodiments, the counter electrode 50 may also serve as a solar cell. For example, the counter electrode 50 may constitute a silicon solar cell and/or a silicon quantum dot solar cell. In more particular, the counter electrode 50 may serve as a photo-conversion layer of a solar cell.

The second electrode 60 may be provided on the counter electrode 50. In example embodiments, the second electrode 60 may be a metal layer. The second electrode 60 may serve as a reflection electrode layer. For example, the second electrode 60 may reflect a solar light 100 incident into the first substrate 10, thereby increasing an amount of the solar light 100 absorbed by the electrochromic layer 30 and the counter electrode 50. Accordingly, it is possible to increase optical efficiency of the counter electrode 50 or the solar cell. Since the second electrode 60 serves as the reflection electrode layer, the electrochromic device 1 can be operated with improved performance (e.g., reduction in operation time required to change its color) and with increased efficiency.

The first electrode 20 and the second electrode 60 may be connected to a voltage source 90.

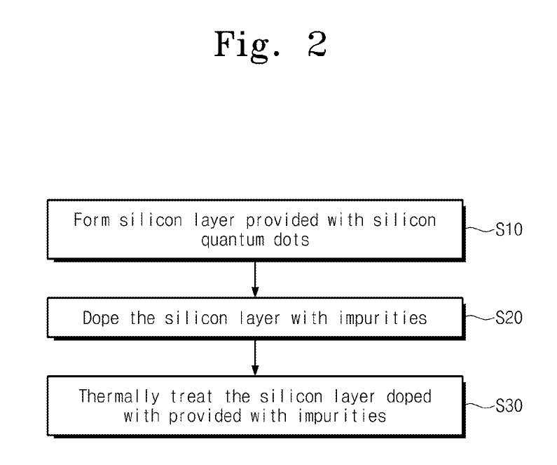

FIG. 2 is a flow chart illustrating a method of fabricating a counter electrode according to example embodiments of the inventive concept.

Referring to FIG. 2 in conjunction with FIG. 1, the formation of the counter electrode 50 may include forming a silicon layer including silicon quantum dots (in S10), doping the silicon layer with impurities (in S20), and then, thermally treating the silicon layer doped with impurities (in S30).

In the case where the counter electrode 50 is a silicon layer, it may be formed using a chemical vapor deposition technique. In example embodiments, the silicon layer may be formed by a plasma enhanced chemical vapor deposition (PECVD). In other example embodiments, the silicon layer may be formed, at a temperature ranging from the room temperature to about 1100° C., using one of atmospheric pressure CVD (APCVD), low pressure CVD (LPCVD), metal organic CVD (MOCVD), and thermal CVD. Alternatively, the counter electrode 50 may be formed at a low temperature (e.g., from about 200° C. to 400° C.).

In the case where the counter electrode 50 is a silicon nitride layer, it may be formed using a silicon source gas and a nitrogen source gas. The silicon source gas may include silane gas. The nitrogen source gas may include a gas containing nitrogen and/or ammonia. For example, the nitrogen source gas may include 5% silane gas diluted by nitrogen gas having 99.9999% purity. The silicon nitride layer may be formed by a PECVD process, in which plasma is used. The use of the plasma enables to grow silicon quantum dots in the silicon nitride layer.

Impurities may be doped in the silicon layer (in S20). In example embodiments, the impurities may be doped using an ion implantation process. The silicon layer may include the first doped layer 51 and the second doped layer 53. One of the first and second doped layers 51 and 53 may be doped with boron (B), aluminum (Al) and/or gallium (Ga), and the other may be doped with phosphorus (P), arsenic (As) and/or antimony (Sb).

A thermal treatment process may be performed to the silicon layer doped with the impurities (in S30). The thermal treatment process may be performed in such a way that oxygen may be prevented from being in-flowed. For example, the silicon layer may be kept in a vacuum before the thermal treatment process and be treated in a nitrogen atmosphere when the thermal treatment process is performed.

The formation of the counter electrode 50 may be performed in such a way that silicon quantum dots may be formed in the silicon layer during the formation of the silicon layer. In the case where the formation of the electrochromic device 1 includes a high temperature process, the electrochromic device 1 may suffer from thermal damage. For example, in the case where the thermal treatment process may be performed at a temperature of about 1100° C. or more, the glass substrate 10 may be damaged. By contrast, according to example embodiments of the inventive concept, the silicon quantum dots may be formed by a low temperature process (such as, the PECVD process), which can be performed at a low temperature of, for example, from about 200° C. to about 400° C. Accordingly, during the formation of the electrochromic device 1 including the counter electrode 50 with a quantum dot solar cell structure, it is possible to prevent a thermal damage from occurring.

The electrochromic device 1 may be operated as follows:

Referring back to FIG. 1, the solar light 100 may be incident to the first substrate 10. For example, the solar light 100 may be partially incident into the counter electrode 50 via the first substrate 10, the first electrode 20, the electrochromic layer 30, and the electrolytic layer 40. The counter electrode 50 may be configured to constitute a solar cell. If the solar light 100 is incident into the counter electrode 50, electron-hole pairs may be generated between the first doped layer 51 and the second doped layer 53. The generated electron-hole pairs may be used to produce electric energy. In example embodiments, the silicon layer may further include the silicon quantum dots. Due to the presence of the silicon quantum dots, it is possible to increase effectively an area to be used for absorption of the solar light 100. This enables to improve light absorptivity of the counter electrode 50 and increase electric energy to be generated from the counter electrode 50. Electric field may be produced between the first electrode 20 and the second electrode 60, which are applied with the electric energy generated from the counter electrode 50. Accordingly, the electrochromic device 1 can be operated in a self-powered manner (i.e., without any external power supply).

In example embodiments, the electrochromic layer 30 may include tungsten oxide (WO₃). If the electric energy generated from the counter electrode 50 is applied to the electrochromic layer 30, the electrochromic layer 30 may produce a chemical reaction described in the following chemical formula, thereby displaying a corresponding color.

WO₃ (transparent)+xe−+xH+<==>HxWO₃ (dark blue), [Chemical Formula]

where x is integer. WO₃ may be transparent state, while HxWO₃ may be reflective.

Hydrogen ions may need to change color of the electrochromic layer 30. The counter electrode 50 may include a silicon layer abound in hydrogen ions. Further, in the case where silicon quantum dots are formed in the counter electrode 50, a concentration of the hydrogen ions may be more increased. The silicon layer of the counter electrode 50 may serve as storage for storing the hydrogen ions, when the electrochromic layer 30 is colorized or decolorized. Accordingly, it is possible to increase a colorizing speed of the electrochromic device 1. The electrolytic layer 40 may be disposed between the counter electrode 50 and the electrochromic layer 30, thereby serving as a delivery path of the hydrogen ions.

The electrochromic layer 30 may be disposed in such a way that the solar light 100 may be incident thereto. Accordingly, the color of the electrochromic layer 30 can be perceived through the first substrate 10.

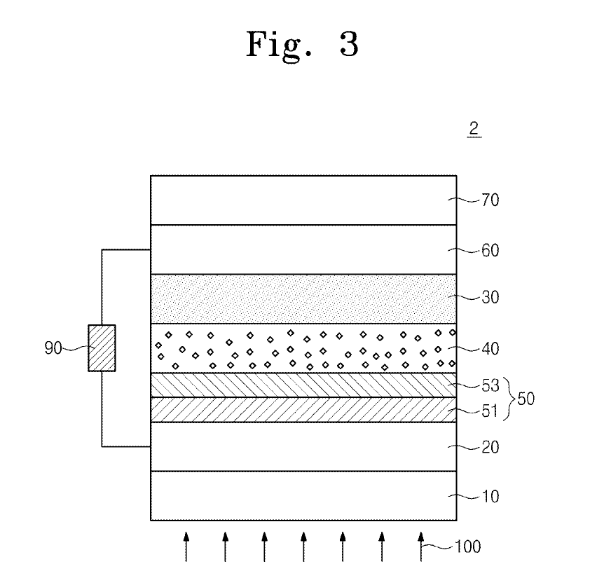

FIG. 3 is a sectional view illustrating an electrochromic device according to other example embodiments of the inventive concept. For the sake of brevity, the elements and features of this example that are similar to those previously shown and described will not be described in much further detail.

Referring to FIG. 3, an electrochromic device 2 may include the first substrate 10, the first electrode 20, the counter electrode 50, the electrolytic layer 40, the electrochromic layer 30, the second electrode 60, and the second substrate 70.

The first substrate 10 may be provided. The first substrate 10 may be a transparent substrate.

The first electrode 20 may be provided on the first substrate 10. The first electrode 20 may include a transparent conductive oxide (TCO) layer.

The counter electrode 50 may be formed on the first electrode 20.

The counter electrode 50 may be a silicon layer. The counter electrode 50 may be at least one of an amorphous silicon layer, a poly silicon layer, a silicon nitride layer, a silicon carbide layer. The counter electrode 50 may further include a silicon nano-crystal layer. This enables to increase the content of hydrogen ion in the counter electrode 50. The counter electrode 50 may include the first doped layer 51 and the second doped layer 53. One of the first and second doped layers 51 and 53 may be doped with boron (B), aluminum (Al), and/or gallium (Ga), and the other may be doped with phosphorus (P), arsenic (As), and/or antimony (Sb).

The counter electrode 50 may be an ion-storing layer. In addition, the counter electrode 50 may be a solar cell (e.g., a silicon solar cell). In example embodiments, the solar cell may be a silicon quantum dot solar cell. In example embodiments, the counter electrode 50 may be a transparent solar cell.

The electrolytic layer 40 may be provided on the counter electrode 50. The electrolytic layer 40 may be a solid organic electrolytic layer or a solid inorganic electrolytic layer. For example, the electrolytic layer 40 may be configured to include tantalum pentoxide (Ta₂O₅).

The electrochromic layer 30 may be provided on the electrolytic layer 40. The electrochromic layer 30 may include a layer of WO₃, TiO₂, MO₃, Ni (OH)₂, CoO₂, IrO₂ and/or polyaniline.

The second electrode 60 may be provided on the counter electrode 50. In example embodiments, the second electrode 60 may be a transparent conductive layer and/or a metal layer. In example embodiments, the second electrode 60 may serve as a reflection electrode layer, and this enables to increase efficiency of the electrochromic device 2.

The second substrate 70 may be provided on the second electrode 60. The second substrate 70 may include a transparent layer and/or a metal layer. The first electrode 20 and the second electrode 60 may be connected to a voltage source 90.

The solar light 100 may be incident to the first substrate 10. In the case where the counter electrode 50 is a transparent solar cell, the color of the electrochromic layer 30 may be displayed through a surface, to which the solar light 100 is incident. Such a color-changing effect may be perceived through the first substrate 10 of the electrochromic device 2. Accordingly, the electrochromic device 2 may be used as a part of an outer wall of a building.

In other example embodiments, the solar light 100 may not be delivered to the electrochromic layer 30. In this case, the color of the electrochromic layer 30 may be displayed through other surface, to which the solar light 100 is not incident. For example, the color-changing effect may be perceived through the second substrate 70 of the electrochromic device 2. For this, the second electrode 60 may be formed of a transparent conductive material. The electrochromic device 2 may be disposed in such a way that the counter electrode 50 faces an outdoor area and the electrochromic layer 30 faces an indoor area.

According to example embodiments of the inventive concept, the electrochromic device 1 and 2 may include the counter electrode 50 serving as a silicon solar cell. For all that, since electrochromic devices can be operated at a low operation voltage of 1.5V or less, the silicon solar cell can be used as a power source for the electrochromic device. In other words, the electrochromic device according to example embodiments of the inventive concept can be self-powered. Since the silicon solar cell has a high content of hydrogen ion, it may also serve as an ion-storing layer. The counter electrode 50 may have silicon quantum dots, and in this case, it is possible to improve energy efficiency and ion-storing ability of the solar cell. Silicon quantum dots can be formed under a low temperature condition, and this enables to improve efficiency in a process of fabricating electrochromic devices.

According to example embodiments of the inventive concept, an electrochromic device may include a counter electrode serving as a silicon solar cell. This enables to realize a self-powered electrochromic device. The counter electrode may be configured to include at least one of a silicon nitride layer, a silicon carbide layer, an amorphous silicon layer, or a poly silicon layer. In example embodiments, the counter electrode may serve as an ion-storing layer. Further, in the case where the counter electrode includes silicon quantum dots, it is possible to improve energy efficiency and ion-storing ability of the solar cell. A silicon layer provided with silicon quantum dots can be formed under a low temperature condition (for example, using PECVD), and this enables to improve efficiency in a process of fabricating electrochromic devices.

While example embodiments of the inventive concepts have been particularly shown and described, it will be understood by one of ordinary skill in the art that variations in form and detail may be made therein without departing from the spirit and scope of the attached claims.

What is claimed is:

1. An electrochromic device, comprising:
first and second substrates spaced apart from and facing each other;
an electrolytic layer between the first substrate and the second substrate;
a first electrode between the first substrate and the electrolytic layer;
a second electrode between the second substrate and the electrolytic layer;
an electrochromic layer between the first electrode and the electrolytic layer; and
a counter electrode between the second electrode and the electrolytic layer,
wherein the counter electrode is a silicon solar cell.

2. The electrochromic device of claim 1, wherein the counter electrode comprises silicon quantum dots.

3. The electrochromic device of claim 1, wherein the counter electrode comprises at least one of silicon nitride, silicon carbide, amorphous silicon, or poly silicon.

4. The electrochromic device of claim 1, wherein the counter electrode is configured to contain or store hydrogen ions.

5. The electrochromic device of claim 1, wherein the counter electrode comprises:
a first doped layer doped with at least one of boron (B), aluminum (Al) or gallium (Ga); and
a second doped layer doped with at least one of phosphorus (P), arsenic (As) or antimony (Sb).

6. A method of fabricating an electrochromic device, comprising:
providing a first substrate and a second substrate;
providing an electrolytic layer between the first substrate and the second substrate;
providing a first electrode between the first substrate and the electrolytic layer;
providing a second electrode between the second substrate and the electrolytic layer;
providing an electrochromic layer between the first electrode and the electrolytic layer; and
providing a counter electrode between the second electrode and the electrolytic layer,
wherein the providing of the counter electrode comprises:
forming a silicon layer provided with silicon quantum dots;
doping the silicon layer with impurities; and
thermally treating the silicon layer doped with the impurities.

7. The method of claim 6, wherein the forming of the silicon layer provided with the silicon quantum dots comprises:
forming a first doped silicon layer; and
forming a second doped silicon layer.

8. The method of claim 7, wherein the forming of the first doped silicon layer is performed using at least one of boron (B), aluminum (Al) or gallium (Ga) as dopants, and the forming of the second doped silicon layer is performed using at least one of phosphorus (P), arsenic (As) or antimony (Sb) as dopants.

9. The method of claim 6, wherein the forming of the silicon layer provided with the silicon quantum dots is performed at a temperature of 1100° C. or less using one of plasma enhanced chemical vapor deposition (PECVD), atmospheric pressure CVD, low pressure CVD, or metal organic CVD.

10. An electrochromic device, comprising:
a first electrode provided on a first substrate;
a counter electrode provided on the first electrode to convert solar energy into electric energy;
an electrolytic layer provided on the counter electrode;
an electrochromic layer provided on the electrolytic layer and electrically connected to the counter electrode;
a second electrode provided on the electrochromic layer; and
a second substrate provided on the second electrode,
wherein the counter electrode includes a silicon layer, in which hydrogen ions are contained.

11. The electrochromic device of claim 10, wherein the electrochromic layer comprises an anodic coloration material or a cathodic coloration material.

12. The electrochromic device of claim 11, wherein the anodic coloration material comprises at least one of vanadium oxide, chromium oxide, manganese oxide, iron oxide, cobalt oxide, nickel oxide, rhodium oxide, or iridium oxide.

13. The electrochromic device of claim 11, wherein the cathodic coloration material comprises titanium oxide, copper oxide, molybdenum oxide, tungsten oxide, niobium oxide, or tantalum oxide.

14. The electrochromic device of claim 10, wherein the electrolytic layer comprises at least one of tantalum pentoxide (Ta₂O₅), poly 2-acrylamino-2-methylpropane sulfonic acid, or poly (ethylene oxide).
